(19) United States
(12) Patent Application Publication
(10) Pub. No.: US 2010/0261008 A1
(43) Pub. Date: Oct. 14, 2010

(54) GAS BARRIER FILM AND METHOD OF PRODUCING THE SAME

(75) Inventor: Tomoyuki KIKUCHI, Kanagawa (JP)

Correspondence Address: YOUNG & THOMPSON, 209 Madison Street, Suite 500, Alexandria, VA, 22314, US

(73) Assignee: FUJIFILM CORPORATION, Tokyo (JP)

(21) Appl. No.: 12/758,416

(22) Filed: Apr. 12, 2010

(30) Foreign Application Priority Data
Apr. 10, 2009 (JP) 2009-095929

(51) Int. Cl. B32B 5/00; H05H 1/24; C23C 14/48; C23C 14/34

(52) U.S. Cl. 428/332; 427/569; 427/579; 427/523; 204/192.12

(57) ABSTRACT

A gas barrier film includes two or more laminates formed on a substrate. each laminate has a organic layer and a inorganic layer stacked in this order. The organic layer directly formed on the substrate includes a (meth)acrylic compound having a glass transition temperature of at least 200° C. and a C—C bond density in the monomer of at least 0.19, and has a thickness of at least 300 nm but less than 1000 nm, and the other organic layer includes a (meth)acrylic compound having a glass transition temperature of at least 105° C. and a C—C bond density in the monomer of at least 0.19, and has a thickness of at least 50 nm but less than 300 nm. The inorganic layers are formed by plasma-enhanced film deposition. A producing method produces the gas barrier film using the plasma-enhanced film deposition.

### BACKGROUND OF THE INVENTION

The present invention relates to a gas barrier film in which two or more laminates each having sequentially formed organic layer and inorganic layer are stacked together, and a method of producing the gas barrier film. More specifically, the present invention relates to a gas barrier film having high adhesion between stacked laminates and excellent gas barrier properties and a method of producing the gas barrier film.

It has heretofore been proposed to form a gas barrier film by continuously depositing an organic layer and an inorganic layer on a surface of an elongated substrate (web of substrate) in a vacuum chamber (see JP 2000-235930 A and JP 2006-95932 A).

JP 2000-235930 A describes subjecting an uncoated thermoplastic support to a treatment selected from the group consisting of heating treatment, reactive plasma treatment, cooling treatment and a combination thereof to form an acrylate monomer composition film on a treated surface of the uncoated thermoplastic support, polymerizing an acrylate monomer in the acrylate monomer composition film to form a crosslinked acrylate layer, forming an SiOₓ or Al₂O₃ oxygen barrier layer on the crosslinked acrylate layer and forming a polymerized acrylate layer on the oxygen barrier layer.

JP 2000-235930 A describes forming the crosslinked acrylate layer and the polymerized acrylate layer by flash evaporation.

JP 2006-95932 A describes a laminate production method in which an inorganic compound layer and an organic compound layer are formed on a substrate in the same vacuum atmosphere without exposure to air. JP 2006-95932 A describes that two or more (meth)acrylic compounds are successively deposited in vacuum, which is followed by irradiation with active energy rays or plasma to cure the organic compound layer.

JP 2006-95932 A describes forming the organic compound layer (active energy ray-cured resin layer) on a gas barrier layer by the foregoing method.

### SUMMARY OF THE INVENTION

As described above, an organic layer is formed on an inorganic layer according to JP 2000-235930 A and JP 2006-95932 A. The organic layer formed on the inorganic layer suffers from poor adhesion at the film interface, thus causing delamination between the inorganic layer and the organic layer in the subsequent step.

In cases where plasma is used to form another inorganic layer on the organic layer formed on the underlying inorganic layer, the plasma may deteriorate the organic layer.

The organic layer proposed by JP 2006-95932 A comprises a mixture of two or more silyl group-containing (meth)acrylic compounds. However, in the subsequent plasma-using film deposition process, ions and radicals in the plasma collide with each other to increase the surface temperature, which deteriorates the organic layer while lowering its adhesion to the overlying inorganic layer and the gas barrier properties.

JP 2000-235930 A describes forming the crosslinked acrylate layer and the polymerized acrylate layer by flash evaporation in a vacuum atmosphere. Therefore, there is no oxygen inhibition, which promotes the curing reaction to increase the internal stress. In cases where another inorganic layer is formed on the polymerized acrylate layer on the underlying inorganic layer, the adhesion between the polymerized acrylate layer and the overlying inorganic layer thus deteriorates.

In cases where another inorganic layer is thus deposited by plasma on the organic layer on the underlying inorganic layer to form a film having the organic layers and the inorganic layers, the film obtained cannot have, at present, excellent adhesion and ultimately excellent gas barrier properties.

The present invention has been accomplished with a view to solving the foregoing prior art problems and an object of the invention is to provide a gas barrier film having high adhesion between layers and excellent gas barrier properties. Another object of the invention is to provide a method of producing the gas barrier film.

In order to achieve the above objects, a first aspect of the present invention provides a gas barrier film comprising: a substrate; a first laminate formed on the substrate and comprising a first organic layer and a first inorganic layer stacked in this order; and at least one second laminate sequentially formed on the first laminate and comprising a second organic layer and a second inorganic layer stacked in this order, wherein the first organic layer directly formed on the substrate comprises a (meth)acrylic compound having a glass transition temperature of at least 200° C. and a C—C bond density in the monomer of at least 0.19, and has a thickness of at least 300 nm but less than 1000 nm, and the second organic layer in the at least one second laminate comprises a (meth)acrylic compound having a glass transition temperature of at least 105° C. and a C—C bond density in the monomer of at least 0.19, and has a thickness of at least 50 nm but less than 300 nm and wherein the first and second inorganic layers are formed by plasma-enhanced film deposition.

The first organic layer and the second organic layer are preferably formed by flash evaporation.

The first and second inorganic layers preferably comprise one of silicon nitride, silicon oxynitride and silicon oxide.

One of plasma-enhanced CVD, sputtering and ion plating is preferably used for the plasma-enhanced film deposition.

The first organic layer preferably comprises the (meth)acrylic compound having a glass transition temperature of at least 210° C., and has a thickness of at least 300 nm but less than 600 nm.

A second aspect of the present invention provides a method of producing a gas barrier film comprising: forming in vacuum on a substrate a first laminate comprising a first organic layer and a first inorganic layer stacked in this order; and sequentially forming in vacuum on the first laminate at least one second laminate comprising a second organic layer and a second inorganic layer stacked in this order, wherein the first organic layer is formed directly on the substrate with a thickness of at least 300 nm but less than 1000 nm using a (meth)acrylic compound having a glass transition temperature of at least 200° C. and a C—C bond density in the monomer of at least 0.19, wherein the second organic layer is formed with a thickness of at least 50 nm but less than 300 nm using a (meth)acrylic compound having a glass transition temperature of at least 105° C. and a C—C bond density in the monomer of at least 0.19, and wherein the first and second inorganic layers are formed by plasma-enhanced film deposition.

The first organic layer and the second organic layer are preferably formed by flash evaporation.

Preferably the substrate is elongated, and the first and second organic layers and the first and second inorganic layers are alternately formed on the substrate which is wrapped on a surface of a drum as it travels in a predetermined direction of travel.

Preferably, the first organic layer is formed on the elongated substrate which is traveling in one direction, the first inorganic layer is formed on the first organic layer, the second organic layer in the at least one second laminate is formed on the first inorganic layer, which is followed by formation of the second inorganic layer in the at least one second laminate as the elongated substrate travels in a direction opposite to the one direction.

One of plasma-enhanced CVD, sputtering and ion plating is preferably used for the plasma-enhanced film deposition.

The first and second inorganic layers preferably comprise one of silicon nitride, silicon oxynitride and silicon oxide.

The present invention is capable of obtaining a gas barrier film having high adhesion between laminates and excellent gas barrier properties.

The present invention is also capable of producing a gas barrier film having high adhesion between organic layers and inorganic layers and excellent gas barrier properties.

### BRIEF DESCRIPTION OF THE DRAWINGS

FIG. 1A is a schematic cross-sectional view showing a gas barrier film according to an embodiment of the present invention;

FIG. 1B is a schematic cross-sectional view showing a gas barrier film according to another embodiment of the present invention;

FIG. 2 is a schematic view showing a production device that may be used to produce the gas barrier films in the embodiments shown in FIGS. 1A and 1B; and

FIG. 3 is a schematic perspective view showing the essential part of a first organic layer-forming unit of the production device used to produce the gas barrier films in the embodiments shown in FIGS. 1A and 1B.

### DETAILED DESCRIPTION OF THE INVENTION

On the following pages, the gas barrier film and the method of producing the gas barrier film according to the present invention are described in detail with reference to the preferred embodiments shown in the accompanying drawings.

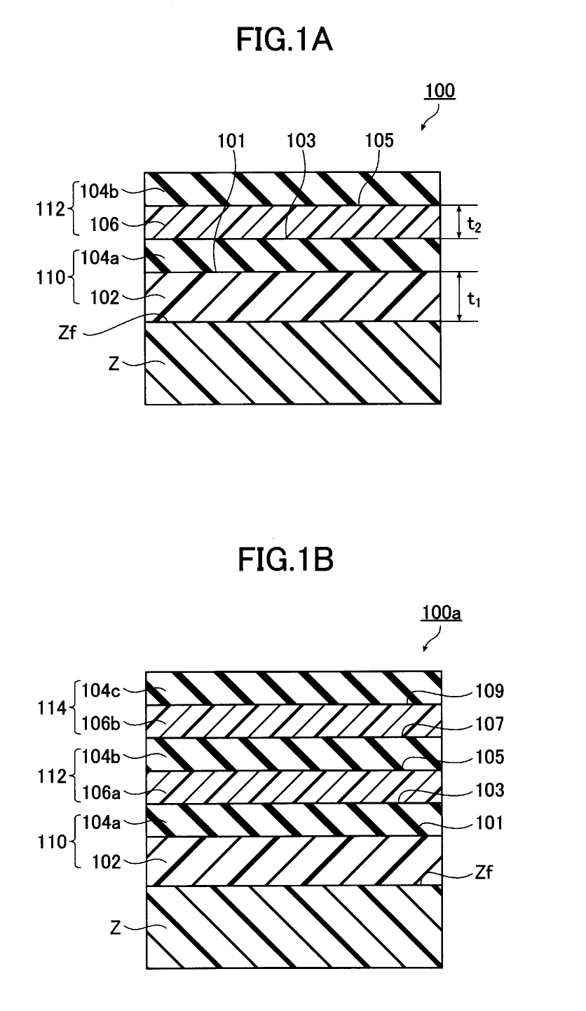

FIG. 1A is a schematic cross-sectional view showing a gas barrier film according to an embodiment of the present invention; and FIG. 1B is a schematic cross-sectional view showing a gas barrier film according to another embodiment of the present invention.

As shown in FIG. 1A, a gas barrier film 100 in this embodiment includes a substrate Z, a first organic layer 102 formed on a surface Zf of the substrate Z, an inorganic layer 104a formed on a surface 101 of the first organic layer 102, a second organic layer 106 formed on a surface 103 of the inorganic layer 104a, and an inorganic layer 104b formed on a surface 105 of the second organic layer 106. The inorganic layers 104a and 104b are formed by plasma-enhanced film deposition.

In this embodiment, the first organic layer 102 and the second organic layer 106 are combined with the inorganic layers 104a and 104b to form laminates 110 and 112, respectively.

The gas barrier film 100 in this embodiment includes two laminates such as the laminates 110 and 112 formed on the surface Zf of the substrate Z.

The present invention is not limited to the case in which the gas barrier film is of a two-laminate structure as in the gas barrier film 100 shown in FIG. 1A which includes the laminates 110 and 112, but the gas barrier film may be of a three-laminate structure as in a gas barrier film 100a as shown in FIG. 1B which includes laminates 110, 112 and 114, or of a multi-laminate structure including four or more laminates. In this case, a second organic layer 106a (106b) is formed on a surface 103 (107) of the inorganic layer 104a (104b). In this way, the first organic layer 102 is formed on the surface Zf of the substrate Z, whereas the second organic layers 106a and 106b are formed on the laminates 110 and 112, respectively.

In the embodiment under consideration, the first organic layer 102 is required to cover and smooth the roughened surface Zf of the substrate Z, to achieve high barrier properties, and to have the surface stability even under exposure to plasma during the formation of the inorganic layer 104a.

Therefore, the material making up the first organic layer 102 contains a (meth)acrylic compound which has a glass transition temperature of at least 200° C. and a C—C bond density in the monomer of at least 0.19. In addition, the first organic layer 102 has a thickness t₁ of at least 300 nm but less than 1000 nm (see FIG. 1A).

The first organic layer 102 has excellent surface smoothness, plasma resistance and gas barrier properties by adjusting the glass transition temperature to 200° C. or more. The first organic layer 102 has poor heat resistance at a glass transition temperature of less than 200° C.

A glass transition temperature of at least 210° C. is preferred because the gas barrier properties and the surface smoothness of the first organic layer 102 are further improved. A glass transition temperature of at least 230° C. is more preferred because the surface stability of the first organic layer 102 under the exposure to plasma is further improved.

There are other physical properties than the rigidity and viscosity which abruptly change at the glass transition point. The glass transition point can be basically determined by knowing the temperature-induced changes from the measurement of the changing physical properties. In particular, the reaction very often involves absorption or generation of heat at the glass transition point and differential scanning calorimetry (DSC) capable of easy measurement is widely used for the determination. The melting point is a point on the temperature axis and is an exact point determined as the temperature at which different phases including solid phase and liquid phase coexist to reach equilibrium. On the other hand, the glass transition point is determined in a nonequilibrium state. The glass transition point is not a point but is in a certain temperature range and varies with the temperature change rate. In other words, the glassy state and the liquid state do not reach equilibrium under the coexistence at a fixed temperature. For practical purposes, a point on a peak (e.g., peak top) appearing in a graph of physical properties measured with respect to the temperature changes is defined as “glass transition point.” The glass transition temperature refers to the temperature at the glass transition point.

In the present invention, the following three methods can be used to measure the glass transition point. (1) The changes in the mechanical properties are measured as the temperature of the sample is slowly increased or decreased; (2) the absorption of heat or the generation of heat is measured as the temperature of the sample is slowly increased or decreased; and (3) the response is measured as the frequency of the periodic force applied to the sample is changed. The method used in (2) is, for example, DSC and the method used in (3) is, for example, dynamic viscoelastic measurement.

The plasma resistance of the first organic layer 102 is improved by using a (meth)acrylic compound having a C—C bond density in the monomer of at least 0.19. The plasma resistance of the first organic layer 102 is deteriorated by using a (meth)acrylic compound having a C—C bond density in the monomer of less than 0.19.

A C—C bond density in the monomer of at least 0.21 is preferred because the first organic layer 102 has further improved plasma resistance and surface smoothness.

In the present invention, the C—C bond density is a parameter indicating the plasma resistance as described above. The C—C bond density is determined by using X-ray photoelectron spectroscopy (hereinafter abbreviated as “XPS”). Waveform separation of the C1s photoelectron peaks is performed by XPS to quantify the C—C, C—O, C—N and C—H bond densities. The thus quantified values are used to calculate the C—C bond density.

The C—C bond density can be calculated by the following mathematical expression 1: wherein N represents the total number of atoms, Nc represents the number of C—C bonds, and No represents the number of C—O bonds.

$$\frac{( Nc - No )}{N} = C - C bond density$$

Examples of the (meth)acrylic compound having a C—C bond density in the monomer of at least 0.19 which makes up the first organic layer 102 include (meth)acrylic resins containing as their main component a polymer of an acrylate monomer and/or a methacrylate monomer. A polymer of a monomer mixture is obtained by polymerizing the monomer mixture. Examples of the (meth)acrylate that may be used include those represented by chemical formulas 1 to 5: However, the (meth)acrylate used in the present invention is not limited to the following:

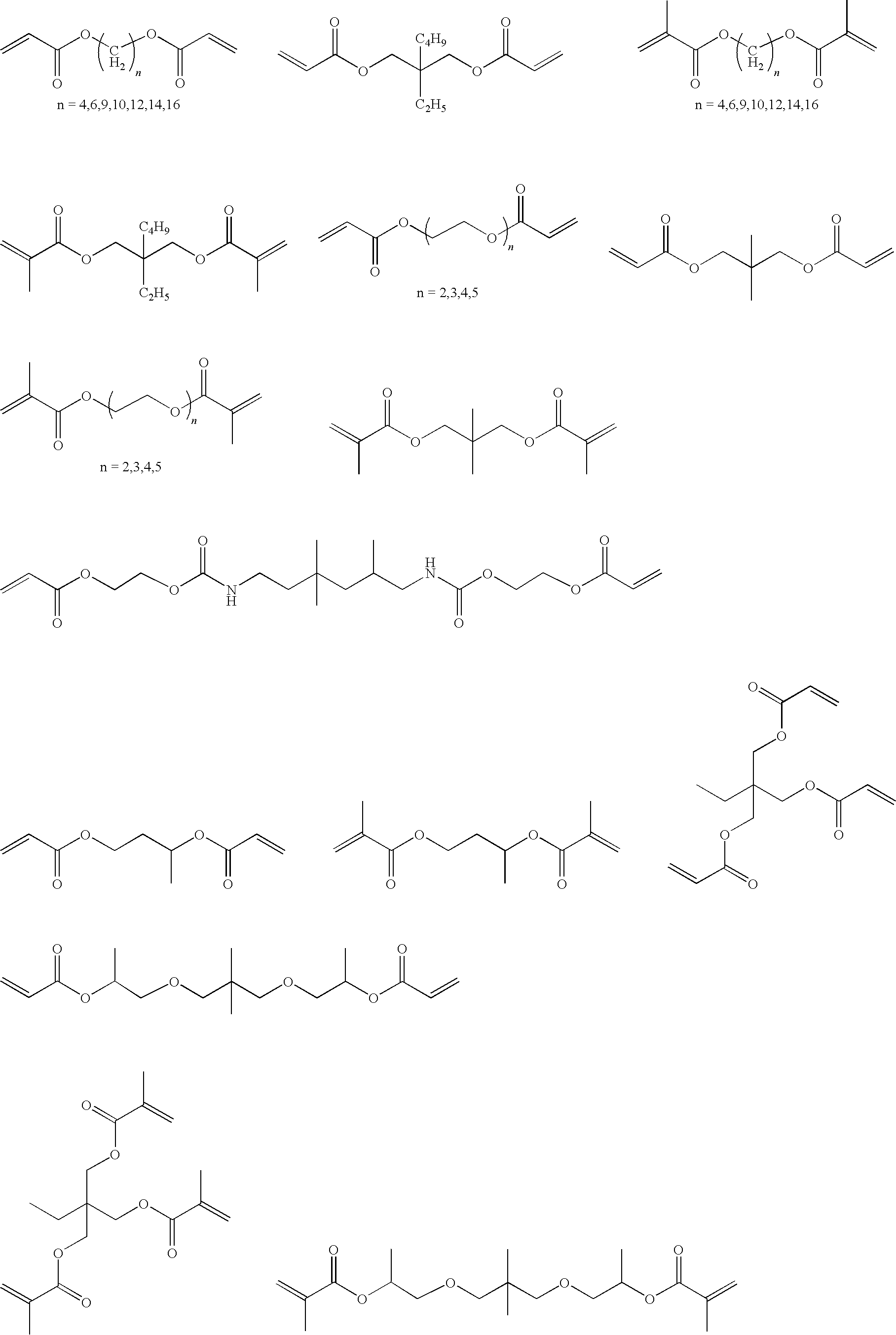

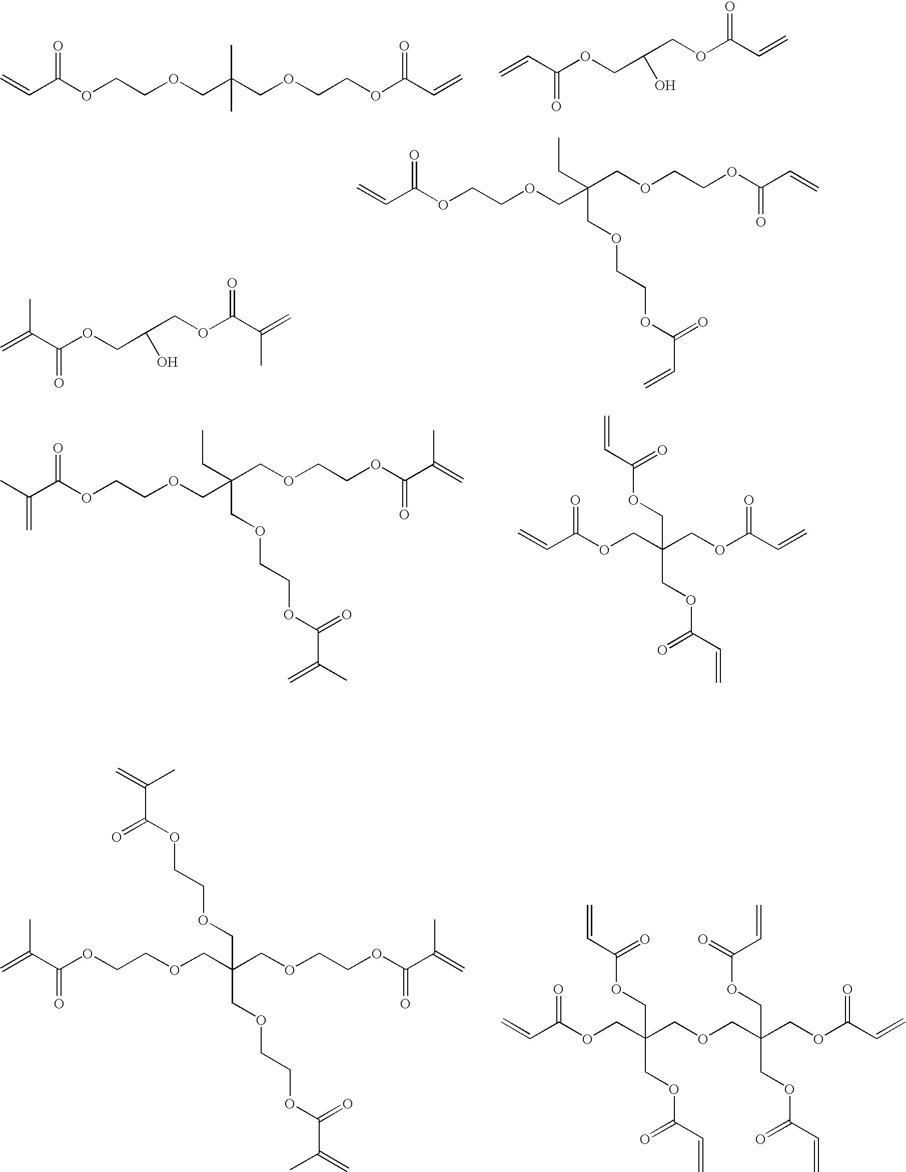

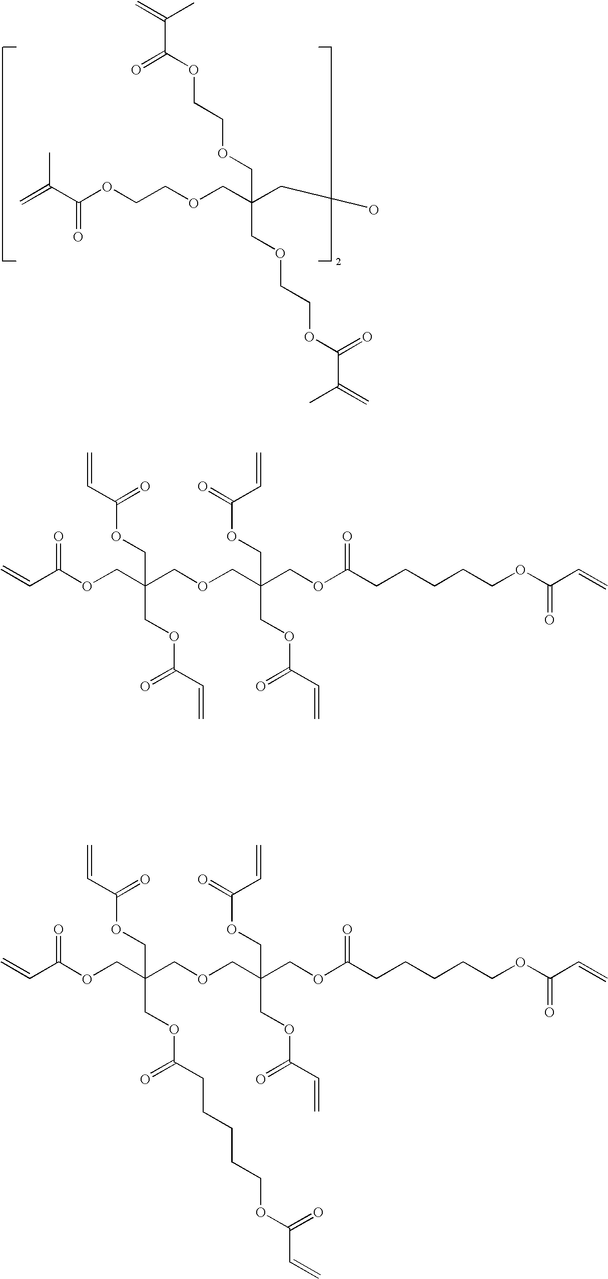

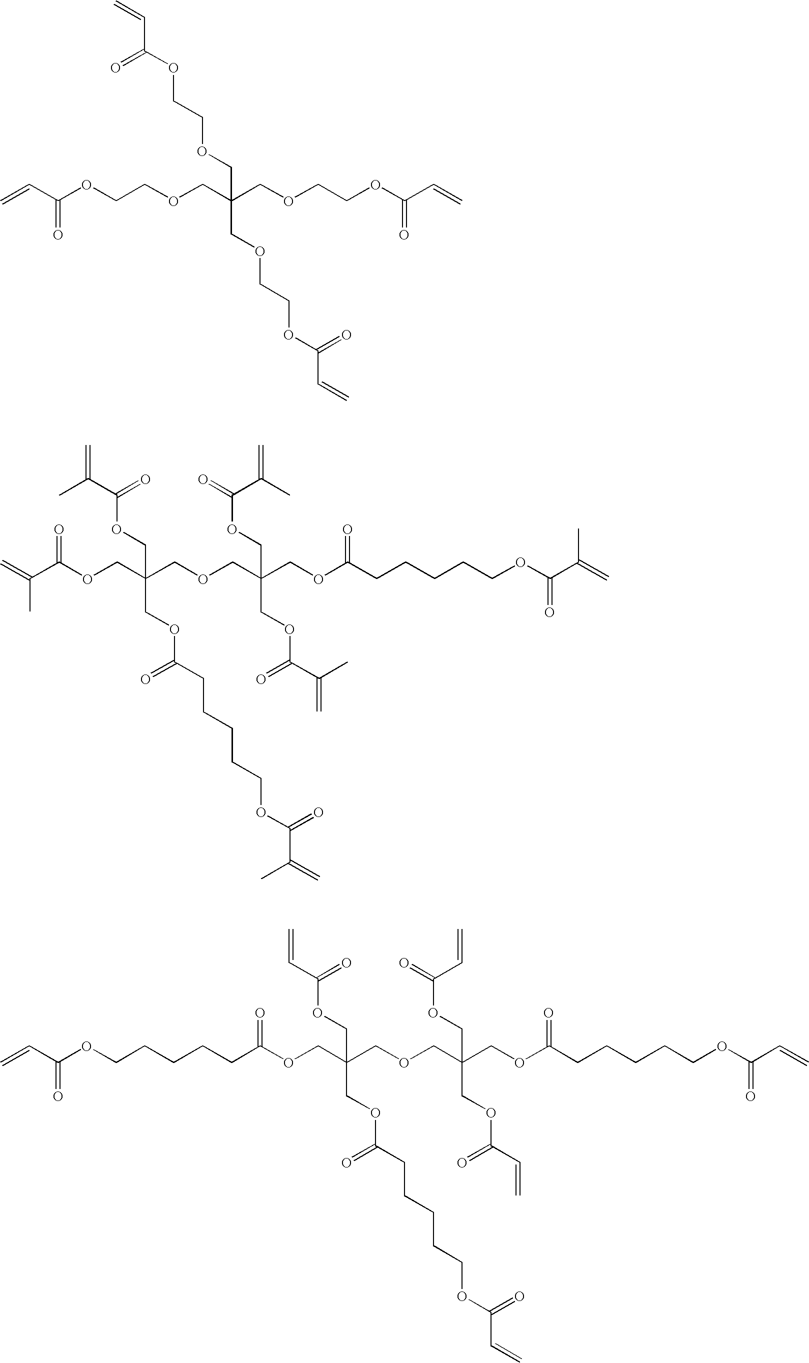

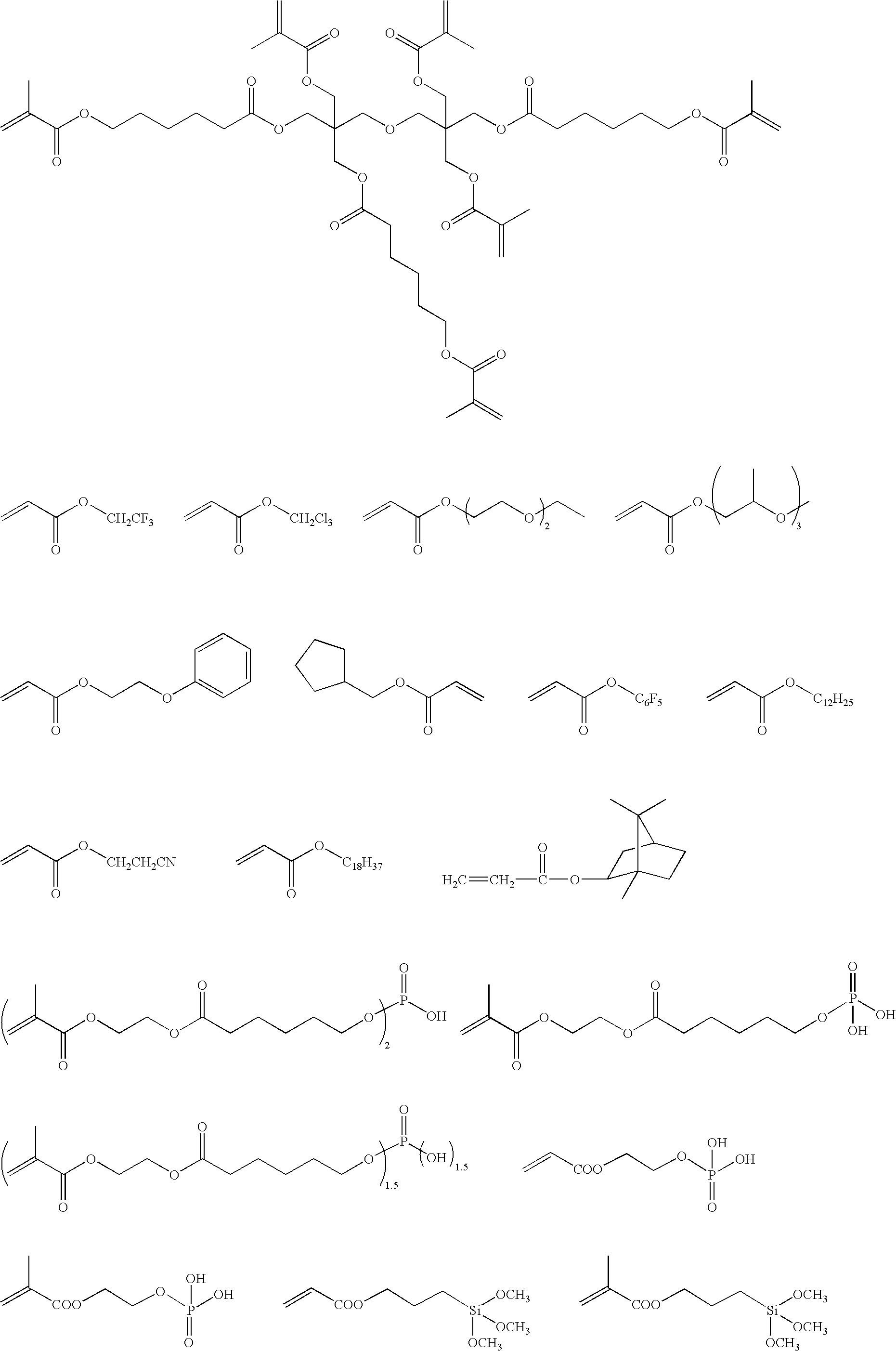

By adjusting the thickness t₁ (see FIG. 1A) to at least 300 nm but less than 1000 nm, dust and defects on the substrate can be covered with the first organic layer 102 to achieve high flatness.

At a thickness t₁ of less than 300 nm, dust and defects on the substrate cannot be fully covered with the first organic layer 102, making it impossible to achieve high flatness.

At a thickness t₁ of 1000 nm or more, it takes much time to deposit the first organic layer 102 and the travel speed cannot be increased, consequently leading to an increase in the cost. The first organic layer 102 more preferably, has a thickness t₁ of at least 300 nm but less than 600 nm.

In the embodiment shown in FIG. 1A, the second organic layer 106 is part of the second laminate 112 and is used to release the stress between the laminates 110 and 112 while achieving high adhesion between the laminates 110 and 112.

In order to achieve the heat resistance of the second organic layer 106 against the plasma-induced increase in the surface temperature during the formation of the inorganic layer 104b while also suppressing the film shrinkage that may be caused by the increase in the surface temperature, the glass transition temperature is adjusted to 105° C. or more.

At a glass transition temperature of less than 105° C., the heat resistance is deteriorated to lower the adhesion between the second organic layer 106 and the inorganic layer 104b formed on the surface 105 of the second organic layer 106.

In the second organic layer 106, the glass transition temperature is preferably at least 150° C. in terms of the flexibility. In the second organic layer 106, the glass transition temperature is preferably less than 200° C. At a glass transition temperature of 200° C. or more, the second organic layer 106 may have decreased flexibility, increased stress and poor adhesion.

The material making up the second organic layer 106 contains a (meth)acrylic compound having a C—C bond density in the monomer of at least 0.19 in consideration of plasma resistance that there is no change of properties even when the second organic layer 106 is exposed to plasma during the formation of the inorganic layer thereon.

The second organic layer 106 may be made of the (meth)acrylic compound having a C—C bond density in the monomer of at least 0.19 as in the first organic layer 102. Therefore, the (meth)acrylic compound having a C—C bond density in the monomer of at least 0.19 which is the material of the second organic layer 106 is not described below in detail.

The plasma resistance and the flexibility of the second organic layer 106 are reduced by using the (meth)acrylic compound having a C—C bond density in the monomer of less than 0.19. Therefore, the adhesion of the second organic layer 106 to the inorganic layer 104b is reduced.

In order to release the stress applied between the laminates 110 and 112 and obtain high adhesion between the laminates 110 and 112, the second organic layer 106 should have a thickness t₂ (see FIG. 1A) of at least 50 nm but less than 500 nm. At a thickness t₂ of less than 50 nm in the second organic layer 106, the function of protecting the inorganic layer during the winding of the film into a roll is reduced.

At a thickness t₂ of 500 nm or more, the second organic layer 106 has a larger internal stress and poor adhesion.

The second organic layer 106 preferably has a thickness t₂ of at least 50 nm but less than 300 nm.

The inorganic layers 104a and 104b serve as gas barriers in the gas barrier film 100. The inorganic layers 104a and 104b comprise, for example, silicon nitride, silicon oxynitride or silicon oxide. Of these, silicon nitride is preferred because of its excellent gas barrier properties.

The inorganic layers 104a and 104b are formed by plasma-enhanced film deposition techniques including plasma-enhanced CVD, sputtering and ion plating.

Various types of plasma-enhanced CVD including capacitively coupled plasma CVD (CCP-CVD), inductively coupled plasma CVD (ICP-CVD), microwave plasma CVD, electron cyclotron resonance CVD (ECR-CVD) and atmospheric pressure barrier discharge CVD are all available. Catalytic CVD (Cat-CVD) may also be applied.

Various materials may be used for the substrate Z as long as a gas barrier layer can be formed by plasma-enhanced CVD. The substrate may be made of organic materials such as plastic films (resin films) or of inorganic materials such as metals and ceramics.

Examples of the substrate that may be advantageously used include substrates made of organic materials such as polyethylene terephthalate (PET), polyethylene naphthalate, polyethylene, polypropylene, polystyrene, polyamide, polyvinyl chloride, polycarbonate, polyacrylonitrile, polyimide, polyacrylate, and polymethacrylate.

If the surface Zf of the substrate Z has topographic features or alien substances having considerably larger sizes than the thickness of the layer to be formed, the gas barrier properties are deteriorated and may not reach a desired level. Therefore, the substrate used is preferably one which has a sufficiently smooth surface and to which few alien substances adhere.

In the gas barrier films 100 and 100a in the embodiments under consideration, the inorganic layers 104a, 104b, 104c are formed and the first organic layer 102 as defined above has the smoothed surface 101 on which the inorganic layer 104a is formed, and the first organic layer 102 also improves the gas barrier properties. In addition, the second organic layer 106, 106a or 106b as defined above highly maintains the adhesion between the laminates 110 and 112 (or 112 and 114), that is, the adhesion to the inorganic layer 104a, 104b or 104c. High gas barrier properties can be thus obtained in the gas barrier films 100 and 100a in the embodiments under consideration.

Next, a production device that may be used to produce the gas barrier film 100 in the embodiment shown in FIG. 1A is described.

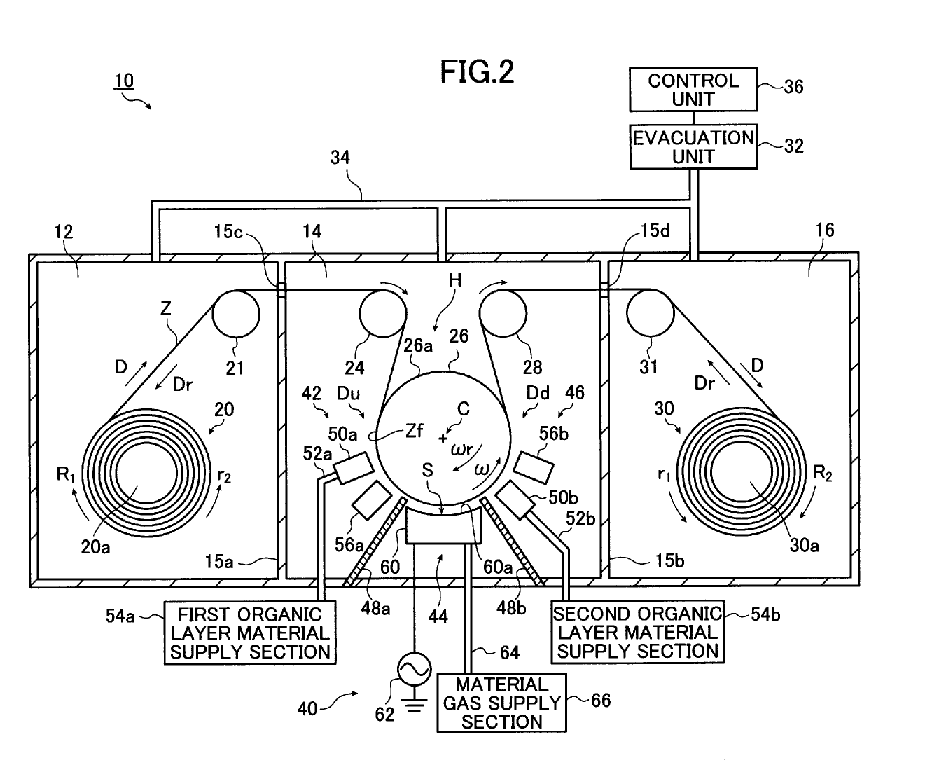

FIG. 2 is a schematic view showing a production device that may be used to produce the gas barrier films in the embodiments of the invention.

The production device 10 shown in FIG. 2 is a device of a roll-to-roll system.

The production device 10 has the function of successively forming the first organic layer 102, the inorganic layer 104a, the second organic layer 106 and the inorganic layer 104b in vacuum as the elongated substrate Z (film material) travels in a longitudinal direction.

In addition to the illustrated members, the production device 10 may also have various members of a plasma CVD device including various sensors, and various members for transporting the substrate Z along a predetermined path, as exemplified by a transport roller pair and a guide member for regulating the position in the width direction of the substrate Z.

The production chamber 10 basically includes a feed chamber 12 for feeding the elongated substrate Z, a film deposition chamber 14 for forming layers on the elongated substrate Z, a take-up chamber 16 for winding up the elongated substrate Z having the layers formed thereon, an evacuation unit 32 and a control unit 36. Various rollers and the evacuation unit 32 are connected to the control unit 36, which controls their operations.

In the production device 10, the feed chamber 12 and the film deposition chamber 14 are partitioned by a wall 15a whereas the film deposition chamber 14 and the take-up chamber 16 are partitioned by a wall 15b; slits of opening 15c and 15d through which the substrate Z can pass are formed in the walls 15a and 15b, respectively. It is preferred to minimize the size of the portions such as the slits of opening 15c and 15d through which the substrate Z passes.

The feed chamber 12, the film deposition chamber 14 and the take-up chamber 16 are constructed by using a material which is commonly employed in a variety of vacuum chambers, such as stainless steel, aluminum, or an aluminum alloy.

In the production device 10, each of the feed chamber 12, the film deposition chamber 14 and the take-up chamber 16 is connected to the evacuation unit 32 via a duct 34. The evacuation unit 32 evacuates the feed chamber 12, the film deposition chamber 14 and the take-up chamber 16 to specified degrees of vacuum.

Each of the feed chamber 12, the film deposition chamber 14 and the take-up chamber 16 is provided with a valve (not shown) for opening to atmosphere (ventilation) or adjustment of the amount of evacuation. The control unit 36 also controls the valve so that the feed chamber 12, the film deposition chamber 14 and the take-up chamber 16 may be opened to atmosphere.

The evacuation unit 32 evacuates the feed chamber 12, the film deposition chamber 14 and the take-up chamber 16 to maintain these chambers at predetermined degrees of vacuum. Each of the feed chamber 12, the film deposition chamber 14 and the take-up chamber 16 is equipped with a pressure sensor (not shown) for measuring the internal pressure.

The evacuation unit 32 has a vacuum pump such as a turbo pump, mechanical booster pump, a dry pump, or a rotary pump. The evacuation unit 32 may be also provided with an assist means such as a cryogenic coil.

The ultimate degree of vacuum that should be created in the feed chamber 12, the film deposition chamber 14 and the take-up chamber 16 by the evacuation unit 32 is not particularly limited as long as an adequate degree of vacuum is maintained in accordance with such factors as the method of film deposition to be performed. The evacuation unit 32 is controlled by the control unit 36.

The present invention is not limited to the embodiment in which all of the feed chamber 12, the film deposition chamber 14 and the take-up chamber 16 are evacuated, and the feed chamber 12 and the take-up chamber 16 which do not require evacuation may not be evacuated.

In order to minimize the adverse effect of the pressures in the feed chamber 12 and the take-up chamber 16 on the degree of vacuum in the film deposition chamber 14, the size of the portions such as the slits of opening 15c and 15d through which the substrate Z passes may be made as small as possible, or a subchamber may be provided between the feed chamber 12 and the film deposition chamber 14 and between the film deposition chamber 14 and the take-up chamber 16 so that the internal pressure of the subchamber is reduced.

The feed chamber 12 is a site for feeding the elongated substrate Z, where a rotary shaft 20a and a guide roller 21 are provided.

The elongated substrate Z is wound on the rotary shaft 20a to form a substrate roll 20, from which the elongated substrate Z is continuously let out. The substrate Z is wound up for example in the counterclockwise direction in FIG. 2.

The rotary shaft 20a is for example connected to a motor (not shown) as a drive source. By means of this motor, the rotary shaft 20a is rotated in a direction R₁ in which the substrate Z is let out; in the embodiment under consideration, the rotary shaft 20a is rotated clockwise in FIG. 2 to feed the substrate Z continuously.

The guide roller 21 guides the substrate Z into the film deposition chamber 14 on a specified travel path. The guide roller 21 is composed of a known guide roller.

In the production device 10 of the embodiment under consideration, the guide roller 21 may be a drive roller or a follower roller. Alternatively, the guide roller 21 may be a roller that works as a tension roller for adjusting the tension that develops during the travel of the substrate Z.

As will be described later, the take-up chamber 16 is a site where the substrate Z having the organic layers and the inorganic layer formed on the surface Zf in the film deposition chamber 14 is wound up; in this take-up chamber 16, there are provided a rotary shaft 30a and a guide roller 31.

The substrate Z is, for example, wound clockwise on the rotary shaft 30a to obtain a take-up roll 30.

The rotary shaft 30a is, for example, connected to a motor (not shown) as a drive source. By means of this motor, the rotary shaft 30a is rotated to wind up the substrate Z.

By means of the motor, the rotary shaft 30a is rotated in a direction R₂ in which the substrate Z is wound up; in the embodiment under consideration, the rotary shaft 30a is rotated clockwise in FIG. 2, whereupon the substrate Z after the film deposition step is, for example, wound up clockwise continuously.

As in the aforementioned guide roller 21, the guide roller 31 guides the substrate Z fed from the film deposition chamber 14 to the rotary shaft 30a on the specified travel path. The guide roller 31 is composed of a known guide roller. Note that like the guide roller 21 in the feed chamber 12, the guide roller 31 may be a drive roller or a follower roller. In addition, the guide roller 31 may serve as a tension roller.

The film deposition chamber 14 is a site where the first organic layer 102, the inorganic layers 104a and 104b, and the second organic layer 106 are formed on the substrate Z.

The film deposition chamber 14 is provided with two guide rollers 24 and 28, as well as a drum 26 and a film deposition area 40.

The guide roller 24, the drum 26 and the guide roller 28 are disposed in this order from the upstream side Du in the direction of travel D.

The guide rollers 24 and 28 are spaced apart by a predetermined distance parallel to each other in a face-to-face relationship. The guide rollers 24 and 28 are disposed so that their longitudinal axes are perpendicular to the direction of travel D of the substrate Z.

The guide roller 24 serves to move the substrate Z fed from the guide roller 21 provided in the feed chamber 12 to the drum 26. The guide roller 24 is rotatable, typically having an' axis of rotation in a direction (this direction is hereinafter referred to as the axial direction) perpendicular to the direction of travel D of the substrate Z, and its length in the axial direction is greater than the length of the substrate Z in a width direction that is perpendicular to the longitudinal direction of the substrate Z (the latter length is hereinafter referred to as the width of the substrate Z).

Note that the substrate roll 20 and the guide rollers 21 and 24 combine together to form a first transport means.

The guide roller 28 serves to move the substrate Z wrapped around the drum 26 to the guide roller 31 provided in the take-up chamber 16. The guide roller 28 is rotatable, typically having an axis of rotation in the axial direction, and its length in the axial direction is greater than the width of the substrate Z.

Note that the guide rollers 28 and 31 as well as the take-up roll 30 combine together to form a second transport means.

Except for the features just described above, the guide rollers 24 and 28 have the same structure as the guide roller 21 provided in the feed chamber 12, so they are not described in detail.

The drum 26 is provided below the space H between the guide rollers 24 and 28. The drum 26 is so positioned that its longitudinal axis is parallel to those of the guide rollers 24 and 28.

The drum 26 is for example in a cylindrical shape and has cylindrical support portions (not shown) provided at both ends thereof. The support portions are rotatably supported by, for example, bearings (not shown) attached to wall surfaces of the film deposition chamber 14. In this way, the drum 26 rotates about an axis of rotation C in a direction of rotation w and a direction of rotation Ωr opposite thereto.

The drum 26 rotates with the substrate Z wrapped around its surface 26a (peripheral surface) to make the substrate Z to travel in the direction of travel D while it is regulated to pass through a specified film deposition position. The length of the drum 26 in the axial direction (longitudinal direction) is greater than the width of the substrate Z.

In addition, the drum 26 may be grounded or connected to a bias power source. Alternatively, the drum 26 may be capable of switching between connection to the bias power source and grounding.

In order to adjust the temperature of each region of the surface 26a, the drum 26 is provided with, for example, a temperature adjusting means (not shown) and a temperature sensor (also not shown) for measuring the temperature of the drum 26. The temperature adjusting means and the temperature sensor are connected to the control unit 36 which adjusts the temperature of each region of the surface 26a of the drum 26 such that it is held at a specified temperature.

The temperature adjusting means of the drum 26 is not particularly limited and various types of temperature adjusting means including one in which a refrigerant is circulated and a cooling means using a Peltier element are all available.

As shown in FIG. 2, the film deposition area 40 includes a first organic layer-forming unit 42, an inorganic layer-forming unit 44 and a second organic layer-forming unit 46 disposed in this order from the upstream side Du to the downstream side Dd in the direction of travel D of the substrate Z.

A partition plate 48a for separating the first organic layer-forming unit 42 and the inorganic layer-forming unit 44 from each other is provided therebetween. A partition plate 48b for separating the inorganic layer-forming unit 44 and the second organic layer-forming unit 46 from each other is provided therebetween.

The first organic layer-forming unit 42 forms the first organic layer 102 (see FIG. 1A) by flash evaporation.

The first organic layer-forming unit 42 includes a first organic layer material vapor deposition section 50a provided so as to face the surface 26a of the drum 26, a first curing section 56a provided on the downstream side of the first organic layer material vapor deposition section 50a in the direction of travel D, and a first organic layer material supply section 54a connected through a first supply pipe 52a to the first organic layer material vapor deposition section 50a.

Although not shown, the first organic layer material vapor deposition section 50a, the first organic layer material supply section 54a and the first curing section 56a of the first organic layer-forming unit 42 are connected to the control unit 36. The control unit 36 controls the first organic layer material vapor deposition section 50a, the first organic layer material supply section 54a and the first curing section 56a.

The first organic layer material supply section 54a evaporates a liquid (meth)acrylic compound (monomer) used as the material of the first organic layer 102 to be formed and supplies vapors of the (meth)acrylic compound through the first supply pipe 52a to the first organic layer material vapor deposition section 50a.

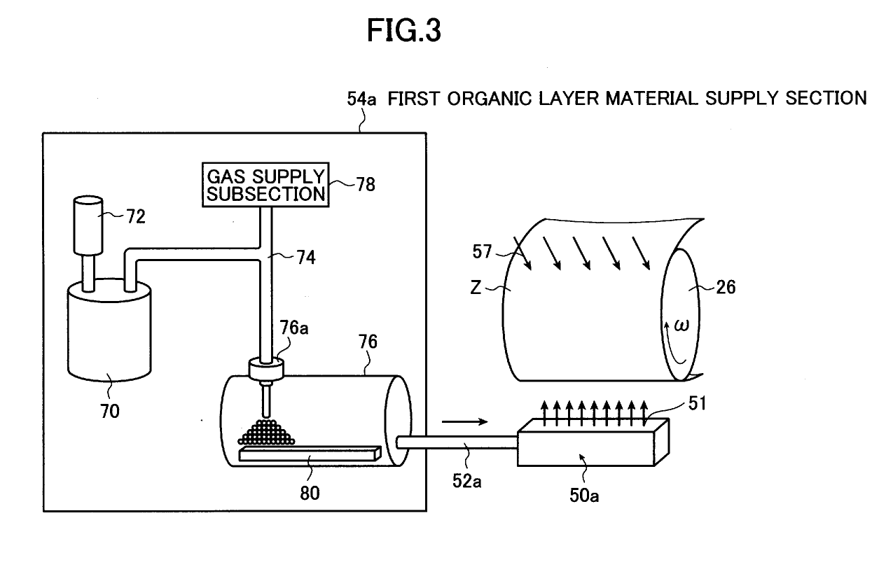

As shown in FIG. 3, the first organic layer material supply section 54a stores the liquid (meth)acrylic compound and is kept at a predetermined reduced pressure, and includes a tank 70 provided with an evacuation means for evacuating the interior to reduce the pressure to a predetermined level and an agitation means, a syringe pump 72 connected to the tank 70, and a liquid injection subsection 76 connected through a supply pipe 74 to the tank 70.

In the first organic layer material supply section 54a, a gas supply subsection 78 is further connected to the liquid injection subsection 76 through the supply pipe 74.

The liquid (meth)acrylic compound in the tank 70 is defoamed by agitation with the agitation means under reduced pressure whereby excess gas is removed therefrom. The syringe pump 72 supplies under pressure the (meth)acrylic compound from the tank 70 to the liquid injection subsection 76 preferably at a syringe pump pressure of 50 to 500 PSI and a flow rate of 0.1 to 50 ml/min. The syringe pump pressure and the flow rate are appropriately set according to the thickness of the layer to be formed.

The liquid injection subsection 76 is of a hollow structure and includes a heating plate 80 in its interior. Although not shown, the liquid injection subsection 76 also includes an evacuation means for evacuating the liquid injection subsection 76 and a heating means for heating the heating plate 80. A liquid droplet injection port 76a is provided at the connection between the liquid injection subsection 76 and the supply pipe 74. Although not shown, the liquid droplet injection port 76a is provided with an ultrasonic application means and a cooling means.

The interior of the liquid injection subsection 76 is in a vacuum state. The liquid (meth)acrylic compound supplied under pressure by the syringe pump 72 is rendered in the form of fine droplets at the liquid droplet injection port 76a to which ultrasonic waves are applied, and injected toward the heating plate 80. Upon contact with the heating plate 80, the (meth)acrylic compound in the form of fine droplets evaporates to form vapors. The vapors of the (meth)acrylic compound pass through the first supply pipe 52a to be supplied to the first organic layer material vapor deposition section 50a.

The evaporation efficiency of the (meth)acrylic compound can be improved by finely dividing the liquid (meth)acrylic compound under the application of ultrasonic waves. In order to prevent the (meth)acrylic compound from thermally curing due to an abrupt increase in the temperature caused by the application of ultrasonic waves to the injection port 76a, a cooling means is preferably used to adjust the temperature of the injection port 76a to, for example, 5 to 50° C. In terms of the evaporation efficiency, the temperature of the heating plate 80 is preferably adjusted in the range of 150° C. to 300° C.

The gas supply subsection 78 of the first organic layer material supply section 54a pushes into the liquid injection subsection 76 the residual monomer within the supply pipe 74 through which the (meth)acrylic compound (monomer) passes. The gas supply subsection 78 includes various gas cylinders containing inert gases such as Ar gas, He gas and N₂ gas, and valves for adjusting the flow rates of the inert gases supplied.

The gas supply subsection 78 pushes out the residual monomer within the supply pipe 74 during the maintenance. Therefore, the gas supply subsection 78 is not used during the usual film deposition.

The first organic layer material vapor deposition section 50a supplies and deposits monomer vapors from the first organic layer material supply section 54a which are used for the first organic layer 102 to the surface Zf of the substrate Z on the drum 26.

The first organic layer material vapor deposition section 50a includes a heating control means (not shown) and heating nozzles 51 for heating the periphery to a temperature which is not less than the aggregation temperature but not more than the evaporation temperature of the material used.

The monomer vapors supplied from the first organic layer material supply section 54a pass through the heating nozzles 51 to form a certain amount of deposits on the substrate Z. In this case, the heating nozzles 51 are preferably held at a temperature of 150° C. to 300° C.

In order to improve the deposition efficiency, the substrate Z is preferably held at a temperature of, for example, −15° C. to 25° C. by cooling the drum 26.

The first curing section 56a cures the (meth)acrylic compound deposited on the substrate Z which makes up the first organic layer 102 to form the first organic layer 102. For example, a UV irradiation means for emitting UV light 57 (see FIG. 3) is used for the first curing section 56a. The UV intensity in the UV irradiation means is preferably in the range of 10 to 100 mW/cm².

An electron beam irradiation means for emitting electron beams or a microwave irradiation means for emitting microwaves may be used for the first curing section 56a.

The inorganic layer-forming unit 44 is provided below the drum 26, and the drum 26, with the substrate Z being wrapped around it, rotates so that the inorganic layer 104a (see FIG. 1A) is formed on the surface 101 of the first organic layer 102 on the substrate Z as it travels in the direction of travel D.

The inorganic layer-forming unit 44 forms the inorganic layer 104a, for example, by CCP-CVD. The inorganic layer-forming unit 44 has a film depositing electrode 60, a radio-frequency power source 62, and a material gas supply section 66. Although not shown, the radio-frequency power source 62 and the material gas supply section 66 of the inorganic layer-forming unit 44 are connected to the control unit 36, which controls their operations.

The film depositing electrode 60 is provided in the lower part of the film deposition chamber 14 such that it is spaced by a specified distance from the surface 26a of the drum 26 to form a space S therebetween. The film depositing electrode 60 is connected to the material gas supply section 66 through a supply pipe 64.

The film depositing electrode 60 is of a type that is, generally called “a shower head electrode” and has a plurality of through-holes (not shown) formed at equal spacings in its surface 60a.

The surface 60a of the film depositing electrode 60 which faces the drum 26 is curved so as to follow the surface 26a of the drum 26. The film depositing electrode 60 is formed such that the surface 60a in any region of the film depositing electrode 60 is at a predetermined distance from the surface 26a of the drum 26 on a line that is perpendicular to the surface 60a and which passes through the axis of rotation C of the drum 26. The film depositing electrode 60 is disposed so that its surface 60a may be on a circle which is concentric with the drum 26 having the surface 26a.

The material gas supplied from the gas material supply section 66 flows through the supply pipe 64 and the plurality of through-holes in the film depositing electrode 60 to be released from the surface 60a of the film depositing electrode 60 so that it is supplied uniformly into the space S.

As shown in FIG. 2, the film depositing electrode 60 is connected to the radio-frequency power source 62, which applies a radio-frequency voltage to the film depositing electrode 60. In this way, a predetermined range of electric field occurs in the space S between the film depositing electrode 60 and the drum 26.

The space S between the surface 26a of the drum 26 and the film depositing electrode 60 serves as a space where plasma is to be generated, hence, as a film deposition space.

The radio-frequency power source 62 is capable of varying the radio-frequency power (RF power) to be applied.

The film depositing electrode 60 and the radio-frequency power source 62 may optionally be connected to each other via a matching box for impedance matching.

In the embodiment under consideration, if a SiO₂ film is to be formed, a TEOS gas is used with oxygen gas as an active species gas. If a silicon nitride film is to be formed, the material gases including SiH₄ gas, NH₃ gas and N₂ gas (dilution gas) are used. If a silicon oxynitride film is to be formed, SiH₄ gas, NH₃ gas, N₂ gas and O₂ gas, or SiH₄ gas, NH₃ gas and NO₂ gas are used.

In this embodiment, a material containing an active species gas and/or a dilution gas is also simply referred to as a material gas.

The material gas supply section 66 may be chosen from a variety of gas introducing means that are employed in CVD apparatuses.

The material gas supply section 66 may supply the space S not only with the material gases but also with various gases used in plasma-enhanced CVD including an inert gas such as argon or nitrogen gas, and an active species gas such as oxygen gas. In the case of introducing more than one species of gas, the respective gases may be mixed together in the same pipe and the mixture be passed through the plurality of through-holes in the film depositing electrode 60 to be supplied into the space S; alternatively, the respective gases may be supplied through different pipes and passed through the plurality of through-holes in the film depositing electrode 60 to be supplied into the space S.

The types of the material gases, the inert gas and the active species gas, as well as the amounts in which they are introduced may be chosen and set as appropriate for various considerations including the type of the film to be formed and the desired film deposition rate.

Note that the radio-frequency power source 62 may be of any known type that is employed in film deposition by plasma-enhanced CVD. The maximum power output and other characteristics of the radio-frequency power source 62 are not particularly limited and may be chosen and set as appropriate for various considerations including the type of the film to be formed and the desired film deposition rate.

The film depositing electrodes 60 is curved to follow the surface 26a of the drum 26, but this is not the sole case of the present invention. As long as it is possible to deposit a film by plasma-enhanced CVD, a rectangular member may be bent in an angular shape; alternatively, a number of flat rectangular electrode plates may be arranged along the direction of rotation ω as if to follow the surface 26a of the drum 26. In this alternative case, electrical conduction is established between the individual electrode plates, which are arranged such that the surface of each electrode plate is at a predetermined distance from the surface 26a of the drum 26 on a line that is perpendicular to the surface of each electrode plate and which passes through the axis of rotation C of the drum 26.

In the embodiment under consideration, the film depositing electrode 60 is of such a configuration that through-holes are formed in the surface 60a of the film depositing electrode plate 60. However, this is not the sole case of the present invention and other configurations are possible as long as they are capable of uniformly supplying the material gas into the space S which serves as the film deposition space. For example, slits of opening may be formed in the bent portions of the film depositing electrode 60 such that the material gas is released through the slits.

The second organic layer-forming unit 46 forms the second organic layer 106 by flash evaporation.

The second organic layer-forming unit 46 only differs from the first organic layer-forming unit 42 in that the second organic layer-forming unit 46 is provided downstream of the inorganic layer-forming unit 44 in the direction of travel D and that the (meth)acrylic compound evaporated in the second organic layer material vapor deposition section 50b is used for the second organic layer 106 (see FIG. 1A); the other structural elements are identical to their counterparts in the first organic layer-forming unit 42 and are not described below in detail.

Although not shown, the second organic layer material vapor deposition section 50b, the second organic layer material supply section 54b and the second curing section 56b of the second organic layer-forming unit 46 are connected to the control unit 36, which controls their operations.

The first organic layer-forming unit 42 is configured in the same manner as the second organic layer-forming unit 46. Therefore, by changing the (meth)acrylic compound, the second organic layer 106 can be formed even in the first organic layer-forming unit 42 and the first organic layer 102 even in the second organic layer-forming unit 46.

In the production device 10, the rotary shaft 20a in the feed chamber 12 and the rotary shaft 30a in the take-up chamber 16 can be rotated in the reverse direction. After having been rewound on the rotary shaft 30a, the substrate having the organic and inorganic layers formed thereon can be unwound from the take-up roll 30 to be rewound on the rotary shaft 20a. In other words, the substrate Z can be made to travel in the direction of travel Dr which is opposite to the direction of travel D. In this way, the inorganic layer 104b can be further formed on the surface 105 of the second organic layer 106. The organic layers and inorganic layers can be thus formed alternately. In other words, the laminates 110 and 112 can be formed on the substrate Z.

In this embodiment, the first organic layer 102 and the second organic layer 106 are both formed by flash evaporation. A solvent-free monomer is used in flash evaporation and therefore no solvent remains in the film. Therefore, the adverse effect of degassing which may be encountered in cases where the temperature of the film surface is increased by plasma used in forming the inorganic layer 104a or 104b is small. This can suppress the reduction of the barrier properties.

On the other hand, if a large amount of solvent remains in the film, the temperature of the film surface is increased by plasma used in forming the inorganic layer 104a or 104b to cause degassing whereby impurities are incorporated in the inorganic layer 104a or 104b to deteriorate the barrier properties. In cases where degassing occurred, the first organic layer 102 and the second organic layer 106 have foam-like defects.

Next, a method of producing the gas barrier film 100 shown in FIG. 1A by using the production device 10 is described.

In the production device 10, the elongated substrate Z that has been wound counterclockwise on the rotary shaft 20a travels from the substrate roll 20 through the guide roller 21 to reach the film deposition chamber 14. In the film deposition chamber 14, the substrate Z travels on the guide roller 24, the drum 26 and the guide roller 28 to reach the take-up chamber 16. In the take-up chamber 16, the elongated substrate Z travels on the guide roller 31 to be wound on the rotary shaft 30a. After the elongated substrate Z has traveled on the travel path, the evacuation unit 32 is actuated to keep the interiors of the feed chamber 12, the film deposition chamber 14 and the take-up chamber 16 at predetermined degrees of vacuum.

The rotary shaft 20a is rotated clockwise by the motor to continuously let out the substrate Z from the substrate roll 20 having the elongated substrate Z wound counterclockwise on the shaft 20a and to make the substrate Z travel to the film deposition area 40.

Next, the first organic layer material supply section 54a of the first organic layer-forming unit 42 in the film deposition area 40 supplies monomer vapors making up the first organic layer 102 to the first organic layer material vapor deposition section 50a. Then, the monomer making up the first organic layer 102 is sprayed through the heating nozzles 51 of the first organic layer material vapor deposition section 50a onto the surface Zf of the substrate Z and deposited to form on the surface Zf a film with a thickness of at least 300 nm but less than 1000 nm and preferably at least 300 nm but less than 600 nm.

Next, the first curing section 56a cures the monomer deposited on the surface Zf of the substrate Z which makes up the first organic layer 102 to form the first organic layer 102. Topographic features at the surface Zf of the substrate Z are covered with the first organic layer 102 formed, and the first organic layer 102 has the surface 101 which is flat.

Next, the substrate Z having the first organic layer 102 formed thereon travels to the inorganic layer-forming unit 44. In the inorganic layer-forming unit 44, a high-frequency voltage is applied from the high-frequency power source 62 to the film depositing electrode 60, and the material gases are supplied from the material gas supply section 66 to the film depositing electrode 60 through the supply pipe 64 and are then uniformly supplied through the through-holes of the film depositing electrode 60 to the space S.

Irradiation of the periphery of the film depositing electrode 60 with electromagnetic waves causes localized plasma to be generated in the space S in the vicinity of the film depositing electrode 60, whereby the material gases are excited and dissociated to form the inorganic layer 104a with a predetermined thickness on the surface 101 of the first organic layer 102 formed on the surface Zf of the substrate Z as the substrate Z travels at a predetermined travel speed.

The first organic layer 102 does not change in properties due to the formation of the inorganic layer 104a, because the (meth)acrylic compound making up the first organic layer 102 has a glass transition temperature of at least 200° C. and a C—C bond density of at least 0.19 and hence the first organic layer 102 exhibits excellent plasma resistance and heat resistance even under exposure to plasma and under high temperatures during the formation of the inorganic layer 104a. The inorganic layer 104a can thus be formed consistently.

Next, the substrate Z having the inorganic layer 104a formed on the surface 101 of the first organic layer 102 travels to the second organic layer-forming unit 46. The second organic layer material supply section 54b of the second organic layer-forming unit 46 supplies monomer vapors making up the second organic layer 106 to the second organic layer material vapor deposition section 50b.

Then, the monomer making up the second organic layer 106 is sprayed through the heating nozzles 51 of the second organic layer material vapor deposition section 50b onto the surface 103 of the inorganic layer 104a and deposited to form on the surface 103 of the inorganic layer 104a a film with a thickness of at least 50 nm but less than 500 nm.

Next, the second curing section 56b cures the monomer deposited on the surface 103 of the inorganic layer 104a which makes up the second organic layer 106 to form the second organic layer 106.

Next, the substrate Z having the second organic layer 106 formed thereon is wound on the rotary shaft 30a. The substrate Z is connected to the rotary shaft 20a of the feed chamber 12 because the inorganic layer 104b is subsequently formed on the surface 105 of the second organic layer 106.

Next, the rotary shaft 30a is rotated by the motor in a direction r₁ opposite to the direction R₂ to unwind the substrate Z from the take-up roll 30, and the substrate Z is then rewound on the rotary shaft 20a as the rotary shaft 20a is rotated by the motor in a direction r₂ opposite to the direction R₁. In this way, the substrate Z is made to travel in the direction of travel Dr which is opposite to the direction of travel D.

The substrate Z having the second organic layer 106 formed thereon thus travels to the inorganic layer-forming unit 44. In the inorganic layer-forming unit 44, a high-frequency voltage is applied from the high-frequency power source 62 to the film depositing electrode 60, and the material gases are supplied from the material gas supply section 66 to the film depositing electrode 60 through the supply pipe 64 and are then uniformly supplied through the through-holes of the film depositing electrode 60 to the space S. The inorganic layer 104b is subsequently formed on the surface 105 of the second organic layer 106 deposited on the substrate Z wrapped around the drum 26. The respective layers of the gas barrier film 100 are thus formed. The gas barrier film 100 in the form of the substrate roll 20 is thus produced.

The second organic layer 106 does not change in properties due to the formation of the inorganic layer 104b, because the (meth)acrylic compound making up the second organic layer 106 has a glass transition temperature of at least 105° C. and a C—C bond density of at least 0.19 and hence the second organic layer 106 exhibits excellent plasma resistance and heat resistance even under exposure to plasma and under high temperatures during the formation of the inorganic layer 104b.

In addition, the film shrinkage of the second organic layer 106 is suppressed even under exposure to plasma and under high temperatures during the formation of the inorganic layer 104b to ensure the adhesion to the inorganic layer 104b formed on the surface 105 thereof.

Therefore, the uppermost inorganic layer 104b of the gas barrier film 100 can be formed with high adhesion without adverse effects on the second organic layer 106. The gas barrier film 100 having the two laminates 110 and 112 can be thus produced.

In the production method of the gas barrier film 100 in the embodiment under consideration, the first organic layer 102, the inorganic layer 104a and the second organic layer 106 are formed on the surface Zf of the substrate Z as it travels in the direction of travel D before the substrate Z having the layers formed thereon is wound into the take-up roll 30. The first laminate 110 and the second organic layer 106 of the second laminate 112 are thus formed. The uppermost inorganic layer 104b is then deposited as the substrate Z travels in the direction of travel Dr which is opposite to the direction of travel D. The second laminate 112 is thus formed. However, the present invention is not limited to this embodiment.

For example, forming means for forming the four layers which make up the gas barrier film 100 may be provided to form the four layers before the substrate Z having been let out from the rotary shaft 20a reaches the rotary shaft 30a.

In the case of producing the gas barrier film 100a in the embodiment shown in FIG. 1B, the same steps as those used to form the gas barrier film 100 shown in FIG. 1A are repeated until the step of forming the inorganic layer 104b of the second laminate 112.

In the method of producing the gas barrier film 100a, the rotary shaft 20a is rotated in the direction r₂ to wound thereon the substrate Z having the inorganic layer 104b of the second laminate 112 formed thereon. Then, the second organic layer 106b of the third laminate 114 is formed on the surface 107 of the inorganic layer 104b in the first organic layer-forming unit 42 as the substrate Z is wound on the rotary shaft 30a rotated in the direction R₂, that is, as the substrate Z travels in the direction of travel D.

In this case, in the first organic layer-forming unit 42, the (meth)acrylic compound making up the second organic layer 106b is supplied from the first organic layer material supply section 54a to the first organic layer material vapor deposition section 50a, from which the (meth)acrylic compound is sprayed and deposited on the inorganic layer 104b and cured in the first curing section 56a to form the second organic layer 106b on the surface 107 of the inorganic layer 104b.

Next, the inorganic layer 104c of the third laminate 114 is formed on the surface 109 of the second organic layer 106b in the inorganic layer-forming unit 44 and the substrate Z having the layers formed thereon is rewound on the rotary shaft 30a rotated in the direction R₂ into the take-up roll 30. The gas barrier film 100a as shown in FIG. 1B can be thus produced.

In the embodiments under consideration, the method of forming the inorganic layers 104a, 104b and 104c is not particularly limited to plasma-enhanced CVD as long as plasma is used. In addition to plasma-enhanced CVD, various other film deposition methods including sputtering and ion plating may be used.

As described above, various other techniques than CCP-CVD can be all used as exemplified by ICP-CVD, microwave plasma CVD, ECR-CVD and atmospheric pressure barrier discharge CVD. Cat-CVD may also be applied.

In the case of forming the inorganic layers 104a, 104b and 104c according to the embodiments under consideration, the temperature adjusting means provided in the drum 26 is preferably used to adjust the temperature of the substrate Z to 120° C. or less and more preferably 80° C. or less.

It is preferred to form the inorganic layers 104a, 104b and 104c by adjusting the temperature of the substrate to 120° C. or less, because the inorganic layers can also be formed on the substrate Z such as a less heat-resistant plastic film substrate (e.g., a PEN substrate) or a substrate using a less heat-resistant organic material as the base material and the inorganic layers formed have a low internal stress.

In addition, it is preferred to form the inorganic layers 104a, 104b and 104c by adjusting the substrate temperature to 80° C. or less using the temperature adjusting means provided in the drum 26, because the inorganic layers can also be formed on a less heat-resistant plastic film substrate (e.g., a PET substrate) and the inorganic layers formed have a low internal stress.

While the gas barrier film and the gas barrier film production method according to the present invention have been described above in detail, the present invention is by no means limited to the foregoing embodiments and it should be understood that various improvements and modifications may of course be made without departing from the scope and spirit of the invention.

### EXAMPLES

The present invention is described below in further detail with reference to specific examples of the invention.

The gas barrier film used in Examples is one obtained by further forming another second organic layer (not shown) on the uppermost inorganic layer 104b of the gas barrier film 100 configured as shown in FIG. 1A.

Gas barrier films in Examples 1 to 3 and Comparative Examples 1 to 8 were prepared.

The first organic layer and the second organic layer in each of the gas barrier films in Examples 1 to 3 and Comparative Examples 1 to 8 had the thicknesses and the physical properties as shown in Table 1.

The first and second organic layers in Examples 1 to 3 and Comparative Examples 1 to 8 are described below in detail.

### Example 1

A mixed solution of 198 g of trimethylolpropane triacrylate (LIGHT-ACRYLATE series TMP-A available from Kyoeisha Chemical Co., Ltd.) and 2 g of ultraviolet polymerization initiator (Ciba Irgacure 907 (trade name) available from Ciba Specialty Chemicals Inc.) was used to form the first organic layer by flash evaporation.

A mixed solution of 60 parts by weight (198 g) of bisphenol A epoxy acrylate (EBECRYL EB600 available from Daicel-UCB Co., Ltd.) and 2 g of ultraviolet polymerization initiator (Ciba Irgacure 907 (trade name) available from Ciba Specialty Chemicals Inc.) was used to form the second organic layer by flash evaporation.

### Example 2

A mixed solution of 198 g of 2-butyl-2-ethyl-propanediol diacrylate (LIGHT-ACRYLATE BEPG-A available from Kyoeisha Chemical Co., Ltd.) and 2 g of ultraviolet polymerization initiator (Ciba Irgacure 907 (trade name) available from Ciba Specialty Chemicals Inc.) was used to form the first organic layer by flash evaporation.

The solution used for the second organic layer was the same as that used for the first organic layer.

### Example 3

A mixed solution of 198 g of trimethylolpropane triacrylate (LIGHT-ACRYLATE series TMP-A available from Kyoeisha Chemical Co., Ltd.) and 2 g of ultraviolet polymerization initiator (Ciba Irgacure 907 (trade name) available from Ciba Specialty Chemicals Inc.) was used to form the first organic layer by flash evaporation.

A mixed solution of 198 g of ethylene oxide-modified trimethylolpropane triacrylate (M-350 (trade name) available from Toagosei Co., Ltd.) and 2 g of ultraviolet polymerization initiator (Ciba Irgacure 907 (trade name) available from Ciba Specialty Chemicals Inc.) was used to form the second organic layer by flash evaporation.

### Comparative Example 1

A mixed solution of 198 g of isocyanuric acid EO-modified di- or triacrylate (M-315 (trade name) available from Toagosei Co., Ltd.) and 2 g of ultraviolet polymerization initiator (Ciba Irgacure 907 (trade name) available from Ciba Specialty Chemicals Inc.) was used to form the first organic layer by flash evaporation.

A mixed solution of 60 parts by weight (198 g) of bisphenol A epoxy acrylate (EBECRYL EB600 available from Daicel-UCB Co., Ltd.) and 2 g of ultraviolet polymerization initiator (Ciba Irgacure 907 (trade name) available from Ciba Specialty Chemicals Inc.) was used to form the second organic layer by flash evaporation.

### Comparative Examples 2 and 3

A mixed solution of 198 g of 2-hydroxy-3-phenoxypropyl acrylate (NK Ester 702A (trade name) available from Shin-Nakamura Chemical Co., Ltd.) and 2 g of ultraviolet polymerization initiator (Ciba Irgacure 907 (trade name) available from Ciba Specialty Chemicals Inc.) was used to form the first organic layer by flash evaporation.

A mixed solution of 60 parts by weight (198 g) of bisphenol A epoxy acrylate (EBECRYL EB600 available from Daicel-UCB Co., Ltd.) and 2 g of ultraviolet polymerization initiator (Ciba Irgacure 907 (trade name) available from Ciba Specialty Chemicals Inc.) was used to form the second organic layer by flash evaporation.

### Comparative Examples 4 and 5

A mixed solution of 198 g of trimethylolpropane triacrylate (LIGHT-ACRYLATE series TMP-A available from Kyoeisha Chemical Co., Ltd.) and 2 g of ultraviolet polymerization initiator (Ciba Irgacure 907 (trade name) available from Ciba Specialty Chemicals Inc.) was used to form the first organic layer by flash evaporation.

A mixed solution of 198 g of polypropylene glycol diacrylate (M-270 (trade name) available from Toagosei Co., Ltd.) and 2 g of ultraviolet polymerization initiator (Ciba Irgacure 907 (trade name) available from Ciba Specialty Chemicals Inc.) was used to form the second organic layer by flash evaporation.

### Comparative Example 6

A mixed solution of 198 g of trimethylolpropane triacrylate (LIGHT-ACRYLATE series TMP-A available from Kyoeisha Chemical Co., Ltd.) and 2 g of ultraviolet polymerization initiator (Ciba Irgacure 907 (trade name) available from Ciba Specialty Chemicals Inc.) was used to form the first organic layer by flash evaporation.

A mixed solution of 198 g of isocyanuric acid EO-modified di- or triacrylate (M-315 (trade name) available from Toagosei Co., Ltd.) and 2 g of ultraviolet polymerization initiator (Ciba Irgacure 907 (trade name) available from Ciba Specialty Chemicals Inc.) was used to form the second organic layer by flash evaporation.

### Comparative Examples 7 and 8

A mixed solution of 198 g of trimethylolpropane triacrylate (LIGHT-ACRYLATE series TMP-A available from Kyoeisha Chemical Co., Ltd.) and 2 g of ultraviolet polymerization initiator (Ciba Irgacure 907 (trade name) available from Ciba Specialty Chemicals Inc.) was used to form the first organic layer by flash evaporation.

A mixed solution of 198 g of ethylene oxide-modified trimethylolpropane triacrylate (M-350 (trade name) available from Toagosei Co., Ltd.) and 2 g of ultraviolet polymerization initiator (Ciba Irgacure 907 (trade name) available from Ciba Specialty Chemicals Inc.) was used to form the second organic layer by flash evaporation.

In Examples, a PEN film (Teonex® Q65FA (trade name) available from Teijin DuPont Films Japan Limited) with a thickness of 100 μm was used for the substrate.

The inorganic layer formed was a silicon nitride film.

The first and second organic layers were formed under the following conditions: syringe pump flow rate of 10 ml/min, syringe pump pressure of 300 PSI, temperature in the organic vapor deposition area of 200° C. and UV dose of 100 mW/cm².

The gas barrier films in Examples 1 to 3 and Comparative Examples 1 to 8 shown in Table 1 were evaluated for the barrier properties and adhesion, and an overall rating was further made based on the barrier properties and adhesion. The evaluation results are shown in Table 2.

The gas barrier films produced in Examples 1 to 3 and Comparative Examples 1 to 8 were evaluated for the barrier properties by measuring the water vapor transmission rate at a temperature of 40° C. and a relative humidity of 90% with a water vapor transmission rate tester (PERMATRAN-W3/31 available from Mocon, Inc.).

The water vapor transmission rate tester has a detection limit of 0.01 g/m²/day. The following method was used when the water vapor transmission rate was less than 0.01 g/m²/day which is the detection limit of the water vapor transmission rate tester.

Calcium metal was first directly vapor-deposited on the surface of the second organic layer which is the uppermost layer of the gas barrier film. The gas barrier film having the deposited calcium layer and the glass substrate were sealed with a commercially available sealant for use in organic EL elements with the calcium layer facing the glass substrate, thereby preparing a measurement sample.

Then, the measurement sample was held under the conditions of a temperature of 40° C. and a relative humidity of 90% and the water vapor transmission rate was determined from the change in the optical density of the calcium metal on the gas barrier film. This makes use of the decrease in the metal gloss of the calcium layer due to hydroxylation or oxidation.

The barrier properties were evaluated by the following criteria: A sample having a water vapor transmission rate of less than 1.0×10⁻⁴ g/m²/day was rated excellent, a sample having a water vapor transmission rate of at least 1.0×10⁻⁴ g/m²/day but less than 1.0×10⁻² g/m²/day was rated good and a sample having a water vapor transmission rate of at least 1.0×10⁻² g/m²/day was rated poor.

As for the adhesion, the uppermost second organic layer on which no inorganic layer was formed was subjected to a cross-cut test according to JIS K5600-5-6 and the results were evaluated as described below.

The adhesion was evaluated based on the results of the cross-cut test: a sample was rated excellent when none of 100 squares peeled off, good when 1 to 25 squares out of 100 peeled off, fair when 26 to 49 squares out of 100 peeled off, and poor when at least 50 squares out of 100 peeled off.

TABLE 1

| | First organic layer | | | Second organic layer | | |
|---|---|---|---|---|---|---|
| | Thickness | Glass transition | C—C bond | Thickness | Glass transition | C—C bond |
| | (nm) | temperature Tg | density | (nm) | temperature Tg | density |
| EX 1 | 500 | 250° C. | 0.21 | 250 | 105° C. | 0.24 |
| EX 2 | 500 | 204° C. | 0.27 | 300 | 204° C. | 0.27 |
| EX 3 | 400 | 250° C. | 0.21 | 250 | 150° C. | 0.21 |
| CE 1 | 500 | 256° C. | 0.18 | 250 | 105° C. | 0.24 |
| CE 2 | 500 | 190° C. | 0.20 | 250 | 105° C. | 0.24 |
| CE 3 | 200 | 190° C. | 0.20 | 250 | 105° C. | 0.24 |
| CE 4 | 500 | 250° C. | 0.21 | 300 | 95° C. | 0.21 |
| CE 5 | 1200 | 250° C. | 0.21 | 300 | 95° C. | 0.21 |
| CE 6 | 500 | 250° C. | 0.21 | 300 | 256° C. | 0.18 |
| CE 7 | 500 | 250° C. | 0.21 | 25 | 150° C. | 0.21 |
| CE 8 | 500 | 250° C. | 0.21 | 700 | 150° C. | 0.21 |

TABLE 2

| | Barrier | | |
|---|---|---|---|
| | properties | Adhesion | Overall rating |
| EX 1 | Good | Good | Good |
| EX 2 | Excellent | Fair | Good |
| EX 3 | Good | Excellent | Good |
| CE 1 | Poor | Excellent | Poor |
| CE 2 | Poor | Good | Poor |
| CE 3 | Poor | Good | Poor |
| CE 4 | Good | Poor | Poor |
| CE 5 | Good | Poor | Poor |
| CE 6 | Good | Poor | Poor |
| CE 7 | Poor | Excellent | Poor |
| CE 8 | Good | Poor | Poor |

The structures and physical properties of the first and second organic layers in Example 1 shown in Table 1 fall within the scope of the present invention. The first organic layer in Example 1 has excellent smoothness, heat resistance and plasma resistance.

The second organic layer has a low internal stress because of the comparatively high flexibility. The second organic layer has high plasma resistance and therefore neither fine projections nor defects occur at the layer surface and its adhesion to the inorganic layer is extremely good.

Therefore, as shown in Table 2, in Example 1, the barrier properties was good, the adhesion was good, and the overall rating was also good.

The structures and physical properties of the first and second organic layers in Example 2 fall within the scope of the present invention. The first organic layer in Example 2 has excellent smoothness, heat resistance and plasma resistance.

In addition, the second organic layer is suitable to improve the barrier properties because of its high heat resistance. The second organic layer has high plasma resistance and therefore neither fine projections nor defects occur at the layer surface and its adhesion to the inorganic layer is good. However, because of the high glass transition temperature and the comparatively low flexibility, the internal stress slightly remains in the second organic layer. The adhesion is slightly inferior but is still at a practical level.

As shown in Table 2, in Example 2, the barrier properties were excellent, the adhesion was fair, and the overall rating was good.

The structures and physical properties of the first and second organic layers in Example 3 fall within the scope of the present invention. The first organic layer in Example 3 has excellent smoothness, heat resistance and plasma resistance.

In addition, as for the second organic layer, the glass transition temperature was within a preferred range, the flexibility was good, and therefore the adhesion was extremely good.

As shown in Table 2, in Example 3, the barrier properties were good, the adhesion was excellent, and the overall rating was good.

In Comparative Example 1, the C—C bond density in the monomer making up the first organic layer is below the lower limit of the present invention and the plasma resistance is low although the smoothness and the heat resistance are excellent. As shown in Table 2, the barrier properties and also the overall rating are poor.

In Comparative Example 2, the glass transition temperature of the material making up the first organic layer is below the lower limit of the present invention and the plasma resistance is low although the smoothness and the heat resistance are excellent. As shown in Table 2, the barrier properties and also the overall rating are poor.

In Comparative Example 3, the thickness of the first organic layer is below the lower limit of the present invention and desired flatness cannot be obtained. As shown in Table 2, the barrier properties and also the overall rating are poor.

In Comparative Example 4, the glass transition temperature of the material making up the second organic layer is below the lower limit of the present invention and the heat resistance is very poor, causing a large number of fine defects at the layer surface although the flexibility is very high. As shown in Table 2, the adhesion of the second organic layer to the inorganic layer and also the overall rating are poor.

In Comparative Example 5, the thickness of the first organic layer exceeds the upper limit of the present invention, and the film deposition rate is low although desired flatness can be obtained. The glass transition temperature of the material making up the second organic layer is below the lower limit defined in the present invention and the heat resistance is therefore very poor, causing a lot of fine defects at the layer surface. As shown in Table 2, the adhesion of the second organic layer to the inorganic layer and also the overall rating are poor.

In Comparative Example 6, the C—C bond density in the monomer making up the second organic layer is below the lower limit of the present invention, the flexibility is slightly low and the plasma resistance is also poor. Therefore, as shown in Table 2, the adhesion of the second organic layer to the inorganic layer and also the overall rating are poor.

In Comparative Example 7, the thickness of the second organic layer is below the lower limit of the present invention and the protective function of the inorganic layer is low. Therefore, as shown in Table 2, the barrier properties and also the overall rating are poor.

In Comparative Example 8, the thickness of the second organic layer exceeds the upper limit of the present invention and the second organic layer has a high internal stress. Therefore, as shown in Table 2, the adhesion of the second organic layer to the inorganic layer and also the overall rating are poor.

What is claimed is:

1. A gas barrier film comprising:
a substrate;
a first laminate formed on the substrate and comprising a first organic layer and a first inorganic layer stacked in this order; and
at least one second laminate sequentially formed on the first laminate and comprising a second organic layer and a second inorganic layer stacked in this order,
wherein the first organic layer directly formed on the substrate comprises a (meth)acrylic compound having a glass transition temperature of at least 200° C. and a C—C bond density in the monomer of at least 0.19, and has a thickness of at least 300 nm but less than 1000 nm, and the second organic layer in the at least one second laminate comprises a (meth)acrylic compound having a glass transition temperature of at least 105° C. and a C—C bond density in the monomer of at least 0.19, and has a thickness of at least 50 nm but less than 300 nm and
wherein the first and second inorganic layers are formed by plasma-enhanced film deposition.

2. The gas barrier film according to claim 1, wherein the first organic layer and the second organic layer are formed by flash evaporation.

3. The gas barrier film according to claim 1, wherein the first and second inorganic layers comprise one of silicon nitride, silicon oxynitride and silicon oxide.

4. The gas barrier film according to claim 1, wherein one of plasma-enhanced CVD, sputtering and ion plating is used for the plasma-enhanced film deposition.

5. The gas barrier film according to claim 1, wherein the first organic layer comprises the (meth)acrylic compound having a glass transition temperature of at least 210° C., and has a thickness of at least 300 nm but less than 600 nm.

6. A method of producing a gas barrier film comprising:
forming in vacuum on a substrate a first laminate comprising a first organic layer and a first inorganic layer stacked in this order; and
sequentially forming in vacuum on said first laminate at least one second laminate comprising a second organic layer and a second inorganic layer stacked in this order,
wherein the first organic layer is formed directly on the substrate with a thickness of at least 300 nm but less than 1000 nm using a (meth)acrylic compound having a glass transition temperature of at least 200° C. and a C—C bond density in the monomer of at least 0.19,
wherein the second organic layer is formed with a thickness of at least 50 nm but less than 300 nm using a (meth)acrylic compound having a glass transition temperature of at least 105° C. and a C—C bond density in the monomer of at least 0.19, and
wherein the first and second inorganic layers are formed by plasma-enhanced film deposition.

7. The method of producing a gas barrier film according to claim 6, wherein the first organic layer and the second organic layer are formed by flash evaporation.

8. The method of producing a gas barrier film according to claim 6, wherein the substrate is elongated, and the first and second organic layers and the first and second inorganic layers are alternately formed on the substrate which is wrapped on a surface of a drum as it travels in a predetermined direction of travel.

9. The method of producing a gas barrier film according to claim 8, wherein the first organic layer is formed on the elongated substrate which is traveling in one direction, the first inorganic layer is formed on the first organic layer, the second organic layer in the at least one second laminate is formed on the first inorganic layer, which is followed by formation of the second inorganic layer in the at least one second laminate as the elongated substrate travels in a direction opposite to the one direction.

10. The method of producing a gas barrier film according to claim 6, wherein one of plasma-enhanced CVD, sputtering and ion plating is used for the plasma-enhanced film deposition.

11. The method of producing a gas barrier film according to claim 6, wherein the first and second inorganic layers comprise one of silicon nitride, silicon oxynitride and silicon oxide.
